(19) United States
(12) Patent Application Publication
(10) Pub. No.: US 2017/0194530 A1
(43) Pub. Date: Jul. 6, 2017

(54) QUANTUM DOT FILM, ITS PREPARATION METHOD, ITS PATTERNING METHOD, AND ITS DISPLAY DEVICE

(71) Applicant: BOE TECHNOLOGY GROUP CO., LTD., Beijing (CN)

(72) Inventors: Tingting Zhou, Beijing (CN); Bin Zhang, Beijing (CN); Yonglian Qi, Beijing (CN); Dini Xie, Beijing (CN)

(21) Appl. No.: 15/256,943

(22) Filed: Sep. 6, 2016

(30) Foreign Application Priority Data
Jan. 4, 2016 (CN) 201610004896.X

(51) Int. Cl. H01L 33/04; B05D 3/02; B05D 1/00

(52) U.S. Cl. CPC H01L 33/04; B05D 1/005; B05D 3/0254; B05D 3/0218

(57) ABSTRACT

A quantum dot film, its preparation method, its patterning method and its display device are provided. Quantum dots can be efficiently dispersed in a photoresist solution to obtain a quantum dot film with a high concentration of quantum dots. The quantum dot film is prepared from the following raw materials: quantum dots, greater than 0 and less than or equal to 60 parts by weight; a dispersant, from 5 to 90 parts by weight; a resin, from 5 to 45 parts by weight; a monomer containing an unsaturated double bond, from 0.5 to 18 parts by weight; a photoinitiator from 0.1 to 3 parts by weight; silicon coupling agent, from 0.1 to 7 parts by weight; an auxiliary, from 0.1 to 1 part of weight; and a solvent, from 40 to 85 parts by weight. This disclosure can be applied in quantum dot film preparation processes.

### TECHNICAL FIELD

The present disclosure relates to a flat panel display technical field, specifically to a quantum dot film, its preparation method, its patterning method and its display device.

### BACKGROUND

A backlight module is a light source provider of a display device, and the total color displayed by the display device originates from the light emitted by the backlight module. The backlight source used in current display devices is typically white backlight which is formed by mixing blue LED light and yellow LED light and has an impure color. Moreover, the monochromatic light obtained by filtering the white backlight through a color filter unit in a color film substrate further contains a plurality of colors in addition to the desired color such that the light finally emitted has defects such as low chroma and very low color saturation. As a result, the display image has a low color gamut, and the color is not sufficiently bright and vivid.

Quantum dots (QD), also known as nanocrystals, have gained much popularity in the display field over recent years owing to their relatively greater color gamut and excellent color saturation, which can improve the image quality. Currently, a quantum dot film prepared from quantum dots can be used as a color film in place of traditional color films in a display device by using the luminescence characteristics of quantum dots.

However, during preparation of a quantum dot film, quantum dots need to be mixed with a photoresist. In this step, the inventors have found that the quantum dots actually cannot be effectively dispersed in an organic solvent typical for formulating a photoresist mother liquor, such that the quantum dots would not be easily dispersed in the photoresist uniformly upon being mixed with the photoresist to prepare the quantum dot film. Moreover, with the increase of the concentration of the quantum dots dissolved in the photoresist, the quantum dots may be aggregated in the photoresist, thereby resulting in incapacity of preparing a quantum dot film containing a high concentration of quantum dots, Additionally, the quantum dot itself has disadvantages such as low luminance and tendency of being quenched. Therefore, the quantum dot film cannot be applied satisfactorily in color films at present.

### SUMMARY

The present disclosure provides a quantum dot film, its preparation method, its patterning method and its display device. The quantum dots can be effectively dispersed in a photoresist solution to obtain a quantum dot film containing a high concentration of quantum dots.

In order to achieve the above purpose, a first aspect of the present disclosure provides a quantum dot film which is prepared from the following raw materials:
quantum dots, greater than 0 and less than or equal to about 60 parts by weight;
a dispersant, from about 5 to about 90 parts by weight;
a resin, from about 5 to about 45 parts by weight;
a monomer containing an unsaturated double bond, from about 0.5 to about 18 parts by weight;
a photoinitiator, from about 0.1 to about 3 parts by weight;
a silicon coupling agent, from about 0.1 to about 7 parts by weight;
an auxiliary, from about 0.1 to about 1 part by weight; and
a solvent, from about 40 to about 85 parts by weight.

Another aspect of the present disclosure provides a display device comprising the quantum dot film as provided by the above technical solution of the present disclosure,

Another aspect of the present disclosure provides a preparation method of a quantum dot film comprising the following steps:
dissolving quantum dots in a dispersant to obtain a quantum dot solution;
mixing a resin, a monomer containing an unsaturated double bond, a photoinitiator, a silicon coupling agent, an auxiliary and a solvent to obtain a photoresist mother liquor;
adding the quantum dot solution dropwise to the photoresist mother liquor under stirring to disperse the quantum dots uniformly so as to obtain a quantum dot spin-coating solution; and
coating the quantum dot spin-coating solution to obtain the quantum dot film.

Another aspect of the present disclosure provides a patterning method of a quantum dot film, which comprises the following steps:
dissolving quantum dots in a dispersant to obtain a quantum dot solution;
mixing a resin, a monomer containing an unsaturated double bond, a photoinitiator, a silicon coupling agent, an auxiliary and a solvent to obtain a photoresist mother liquor;
adding the quantum dot solution dropwise to the photoresist mother liquor under stirring to disperse the quantum dots uniformly so as to obtain a quantum dot spin-coating solution;
coating the quantum dot spin-coating, solution onto a substrate to form a quantum dot film; and
subjecting the quantum dot film to prebaking, exposure, development and postbaking processes sequentially so as to obtain a patterned quantum dot film.

The present disclosure provides a quantum dot film containing quantum dots and a dispersant capable of effectively dispersing the quantum dots. In the prior art, quantum dots are directly dissolved in a photoresist. In contrast, dissolving quantum dots in a photoresist according to the present disclosure comprises first dispersing the quantum dots by means of a dispersant, and then dissolving the dispersed quantum dots in the photoresist, which can effectively avoid poor dissolvability of the quantum dots in the photoresist and aggregation of the quantum dots with a high concentration in the photoresist. Enhanced dispersion of the quantum dots in the photoresist would increase parts by weight of the quantum dots being dissolved in the photoresist, and therefore a quantum dot film having a high concentration of quantum dots can be prepared.

### BRIEF DESCRIPTIONS OF THE DRAWINGS

In order to clearly illustrate the technical solutions of embodiments of the present disclosure or the technical solutions in the prior art, the drawings used for describing the embodiments or the prior art are briefly described below. Apparently, the drawings described below merely relate to some embodiments of the present disclosure, and other drawings can be obtained by a person skilled in the art based on the accompanying drawings without paying any inventive work.

FIG. 1 is a principle schematic diagram of dissolving quantum dots in a photoresist with/without a dispersant;

FIG. 2 is a flow chart of a preparation method of a quantum dot film according to an embodiment of the present disclosure;

FIG. 3 is a flow chart of a patterning method of a quantum dot film according to an embodiment of the present disclosure;

FIG. 4 is a fluorescence spectrum having quantum dots at different parts by weight according to embodiments of the present disclosure; and

FIG. 5 is a patterning effect graph of the quantum dot film No. 3 in Table 2 of the present disclosure.

### DETAILED DESCRIPTION

The technical solutions of embodiments of the present disclosure will be described in a clearly and fully understandable way in connections with the related drawings. It is obvious that the described embodiments are just a part but not all of the embodiments of the present disclosure. Based on the described embodiments herein, those skilled in the art can, without any inventive work, obtain other embodiments, which should be within the scope of the present disclosure.

An embodiment of the present disclosure provides a quantum dot film which is prepared from the following raw materials:
quantum dots, greater than 0 and less than or equal to about 60 parts by weight;
a dispersant, from about 5 to about 90 parts by weight;
a resin, from about 5 to about 45 parts by weight;
a monomer containing an unsaturated double bond, from about 0.5 to about 18 parts by weight;
a photoinitiator, from about 0.1 to about 3 parts by weight;
a silicon coupling agent, from about 0.1 to about 7 parts by weight;
an auxiliary, from about 0.1 to about 1 part of weight; and
a solvent, from about 40 to about 85 parts by weight.

In this embodiment, the components in the formulation of the quantum dot film may approximately be divided into two parts:
one part for forming a quantum dot solution, specifically comprising quantum dots and a dispersant; and
the other part for forming a photoresist solution, specifically comprising a resin, a monomer containing an unsaturated double bond, a photoinitiator, a silicon coupling agent, an auxiliary, and a solvent.

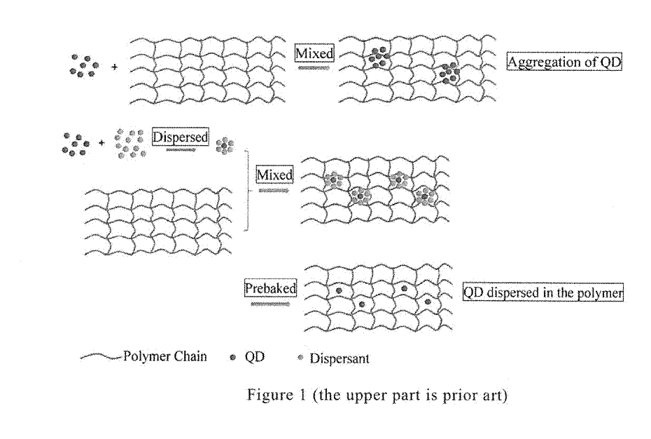

The quantum dot film thus formed is prepared by mixing the quantum dot solution and the photoresist solution and then coating the mixed solution. As shown by the lower reaction in FIG. 1, in this embodiment, quantum dots are firstly mixed with a dispersant to form dispersed quantum dots, and then the dispersed quantum dots are mixed with a photoresist to disperse the quantum dots into the photoresist uniformly. In the quantum dot film formed by this embodiment, the quantum dots can be dispersed in the photoresist polymer uniformly. In contrast, direct mixing quantum dots with a photoresist in the prior art leads to aggregation of the quantum dots in the photoresist polymer (as shown by the upper reaction in FIG. 1).

In the above-mentioned embodiment, the resin may be selected from copolymers of unsaturated anhydride/carboxylic acid and styrene, the derivatives thereof, etc., and specifically, selected from any one or a combination of two and more of unsaturated polyester, epoxy acrylate, polyurethane acrylate, polyester acrylate, polyether acrylate, and mono-functional monomers, multi-functional monomers, such as dipentaerythritol pentaacrylate (DPHA), dipentaerythritol hexaacrytate, dipropylene glycol diacrylate, tripropylene glycol diacrylate, trimethylolpropane triacrylate (TMPTA), di-(trimethylol propane) tetraacrylate and aliphatic polyurethane acrylate.

The monomer containing an unsaturated double bond may be selected from any one or a combination of two and more of 1,6-hexanediol diacrylate, di-propylene glycol diacrylate, tri-propylene glycol diacrylate, trimethylol propane triacrylate, ethoxylated trimethylol propane triacrylate, pentaerythritol tetraacrylate, di-(trimethylol propane) tetraacrylate and dipentaerythritol pentaacrylate.

The photoinitiator may be selected from any one or a combination of two and more of diimidazole compounds, benzoin compounds, multinuclear quinone compounds, benzophenone compounds, acetophenone compounds, triazine compounds, diazo compounds, anthraquinone compounds, xanthenone compounds, oxime ester compounds, iodonium salts and sulfonium salts.

The silicon coupling agent may be selected from any one or a combination of two and more of KH550 (γ-amino propyl triethoxy silane), KH560 (γ-glycidoxy propyl trimethoxy silane), KH570 (γ-(methacryloxy)propyl trimethoxy silane), KH792 (N-(β-amino ethyl)-γ-aminopropyl trimethoxy(ethoxy)silane), DL602 (N-(β-aminoethyl)-γ-aminopropyl methyldimethoxysilane) and DL171 (vinyl trimethoxysilane).

The auxiliary may be selected from any one or a combination of two and more of a wet leveling agent, a defoamer, a UV absorbent, an adhesive promoter.

The solvent may be selected from any one or a combination of two and more of aliphatic alcohol, ethylene glycol monomethyl ether, ethylene glycol monoethyl ether, ethylene glycol monopropyl ether, ethylene glycol monobutyl ether, diethylene glycol diethyl ether ethyl actate, methyl ethyl ketone, methyl isobutyl ketone, monomethyl ether ethylene glycol ester, γ-butyrolactone, ethyl 3-ethoxypropionate, butyl carbitol, butyl carbitol acetate, propylene glycol monomethyl ether, propylene glycol monomethyl ether acetate, cyclohexane, xylene and isopropanol. Among them, the solvent may be selected from any one or a combination of two and more of propylene glycol monomethyl ether, propylene glycol monomethyl ether acetate, cyclohexane, butyl carbitol, butyl carbitol acetate and γ-butyrolactone.

The present disclosure provides a quantum dot film containing quantum dots and a dispersant which can efficiently disperse the quantum dots. In the prior art, quantum dots are directly dissolved in a photoresist. In contrast, dissolving quantum dots in photoresist according to the present disclosure comprises first dispersing the quantum dots by means of a dispersant, and then dissolving the dispersed quantum dots in the photoresist, such that poor dissolvability of quantum dots in a photoresist and aggregation of the quantum dots of a high concentration in the photoresist may be efficiently avoided. Enhanced dispersion of the quantum dots in the photoresist would improve parts by weight of the quantum dots being dissolved in the photoresist, and thereby a quantum dot film having a high concentration of quantum dots can be prepared.

For example, the quantum dot film comprises greater than 0 wt % and less than or equal to about 60 wt % of the quantum dots after being dried. Specifically, after removal of the solvent, the auxiliary and other related liquid components from the formulation, the quantum dot dry film may comprise up to about 60 wt % of quantum dots. Compared with the quantum dot film in prior art, in which quantum dots can only reach about 20 wt % in the dry film, the embodiment of the present disclosure provides a quantum dot film in which the parts by weight of the quantum dots are significantly improved.

As would be appreciated, although the quantum dots may reach 60 wt % in the quantum dot dry film, up to about 38 wt % is enough in practice at present. The main reason for this is high cost of quantum dots. Although adding more quantum dots may improve the color gamut and the quality of the display device, the process cost may be correspondingly increased much more. Moreover, more quantum dots are not necessary, because quantum dots may be aggregated and the brightness may be reduced instead. Meanwhile, when a patterned quantum dot film is formed subsequently, the edge effect of the film may be influenced by too many quantum dots. Therefore, in practice, the quantum dots in the quantum dot dry film of this embodiment may be up to about 38 wt %. Specifically, the quantum dots in the quantum dot dry film may be any value which is greater than 0 wt % and less than or equal to about 38 wt %, such as 3 wt %, 10 wt %, 15 wt %, 20 wt %, 25 wt %, 30 wt %, 35 wt %, etc., which would not be listed one by one herein.

For instant, the quantum dot film has a dry film thickness of from about 1.5 μm to about 3 μm. The thickness of the quantum dot film is conventional in large scale production processes. In the preparation of the quantum dot film, the thickness of the quantum dot film may be affected by the film coating rotation rate. Taking 6 revolutions per second for example, the quantum dot film obtained after baking has a thickness of from about 1.5 μm to about 1.8 μm. If a thicker quantum dot film is desired according to process requirements, the above-mentioned film coating rotation rate may be reduced correspondingly, to for example, about 3 revolutions per second, 4 revolutions per second, 5 revolutions per second, etc. As would be appreciated, a greater thickness of the quantum dot film within the above-mentioned range is better, because this may ensure the brightness of the quantum dot film obtained finally.

For example, the quantum dot comprises at least one or a combination of two or more of CdS, CdSe, CdTe, ZnS, ZnSe, ZnTe, HgS, HgTe, GaN, GaAs, InP, and InAs. In the embodiment, the quantum dot material for preparing the quantum dot film may be widely selected, for example selected from one or a combination of two or more of those listed above. The quantum dot material has a wide source and good universality. Additionally, the used quantum dots may be of uniform mixing type, gradient mixing type, core-shell type, or united type, which are not specifically limited herein.

For example, the quantum dot is CdSe/ZnS type red quantum dot or CdSe/ZnS type green quantum dot. The quantum dot film may be composed from quantum dot sections of different colors. In each quantum dot section, the quantum dots are selected according to the different color of the light to be emitted. For example, when a red light is desired, CdSe/ZnS type red quantum dots may be selected; and when a green light is desired, CdSe/ZnS type green quantum dots may be selected. It would be appreciated that the type of the selected quantum dots is not specifically limited herein as long as light of a desired different color can be emitted.

In a preferred embodiment, the CdSe/ZnS type red quantum dot is about 3-40 parts by weight, and the CdSe/ZnS type green quantum dot is about 3-40 parts by weight. In order to enable the parts by weight of the quantum dots to reach about 38% in the quantum dot dry film obtained finally, for example about 3-40 parts by weight of red quantum dots or green quantum dots are added in this embodiment. It would be appreciated that a person skilled in the art may add the quantum dots within the above-mentioned range of parts by weight according to the requirement of the brightness of the quantum dot film obtained finally.

In a preferred embodiment, the dispersant is selected from at least one or a combination of two or more of chloroform, tetrahydrofuran, methylene chloride, toluene, n-hexane, methanol, ethanol, propanol, butanol, acetone, dioxane, dimethyl formamide and dimethyl sulfoxide. In this embodiment, only some of the dispersants are listed, wherein chloroform and tetrahydrofuran are preferred, and chloroform is most preferred. The selection criterion is the dispersion effect of the quantum dots after addition of the dispersant. It would be appreciated that a person skilled in the art may select dispersants according to different types of quantum dots in order to better disperse the quantum dots. It would be appreciated that the amount of the dispersant added is for example about 20-60 parts by weight.

Another aspect of the embodiments of the present disclosure provides a display device comprising the quantum dot film as described in the above-mentioned embodiment. The above-mentioned quantum dot film contains quantum dots and a dispersant capable of dispersing the quantum dots effectively, such that the quantum dots can be better dispersed in a photoresist, which avoids aggregation of the quantum dots in the photoresist. If the quantum dot film is used in the display device, the brightness and color gamut of light can be effectively improved during transmission in the display device, thereby improving the overall performance of the display device and the quality of the display image. It would be appreciated that the display device provided in this embodiment may be a liquid crystal display or a white or blue OLED display; wherein a blue OLED display is preferred.

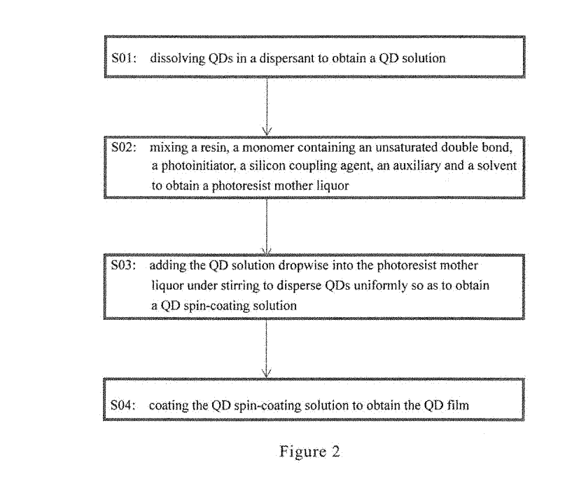

As illustrated in FIG. 2, another aspect of the embodiments of the present disclosure provides a preparation method of a quantum dot film, the preparation method comprising the following steps:

Step 1: dissolving quantum dots in a dispersant to obtain a quantum dot solution.

In this step, greater than 0 and less than or equal to about 60 parts by weight of quantum dots are dissolved in from about 5 to about 90 parts by weight of a dispersant to obtain a quantum dot solution, wherein the quantum dot can be at least one or a combination of two or more of CdS, CdSe, CdTe, ZnS, ZnSe, ZnTe, HgS, HgTe, GaN, GaAs, InP, and InAs; and the dispersant can be selected from at least one or a combination of two or more of chloroform; tetrahydrofuran, methylene chloride, toluene, n-hexane, methanol, ethanol, propanol, butanol, acetone, dioxane, dimethyl formamide and dimethyl sulfoxide. For example, the amount of the dispersant added is from about 20 to about 60 parts by weight.

Step 2: mixing a resin, a monomer containing an unsaturated double bond, a photoinitiator, a silicon coupling agent, an auxiliary and a solvent to obtain a photoresist mother liquor.

In this step, from about 5 to about 45 parts by weight of a resin, from about 0.5 to about 18 parts by weight of a monomer containing an unsaturated double bond, from about 0.1 to about 3 parts by weight of a photoinitiator, from about 0.1 to about 7 parts by weight of a silicon coupling agent, from about 0.1 to about 1 part of weight of an auxiliary and from about 40 to about 85 parts by weight of a solvent are mixed to obtain a photoresist mother liquor.

It would be appreciated that in this embodiment, the sequences of Step 1 and Step 2 can be interchanged.

Step 3: adding the quantum dot solution dropwise to the photoresist mother liquor under stirring to disperse the quantum dots uniformly so as to obtain a quantum dot spin-coating solution.

In this step, the quantum dot solution obtained above is added dropwise to the photoresist mother liquor. Dropwise adding or slow adding enables the quantum dot solution to be disperse more uniformly in the photoresist mother liquor so as to obtain a clear and translucent quantum dot spin-coating solution which is uniformly dispersed.

Step 4: coating the quantum dot spin-coating solution to obtain a quantum dot film.

In this step, the above-mentioned quantum dot spin-coating solution can be coated by spin coating to obtain a quantum dot film. It would be appreciated that the specific method for coating a quantum dot spin-coating solution is not specifically limited in this embodiment.

An embodiment of the present disclosure provides a preparation method of a quantum dot film. In this preparation method, quantum dots are first dissolved in a dispersant, and the quantum dots dissolved in the dispersant are then dissolved in a photoresist to effectively disperse the quantum dots in the photoresist. Because the quantum dots are effectively dispersed in the photoresist, the parts by weight of the quantum dots dissolved in the photoresist can be accordingly increased such that a quantum dot film containing a high concentration of quantum dots can be prepared. This method is simple and easy to operate, and solves the technical problem of inability to prepare a quantum dot film containing a high concentration of quantum dots in the prior art.

For example, in Step 3, quantum dots are dispersed uniformly by means of ultrasound or stirring. After the quantum dot solution is added dropwise to the photoresist mother liquor, the mixed solution can be treated by means of ultrasound or stirring to disperse the quantum dot solution in the photoresist mother liquor more uniformly, thereby obtain a clear and translucent quantum dot spin-coating solution which is uniformly dispersed.

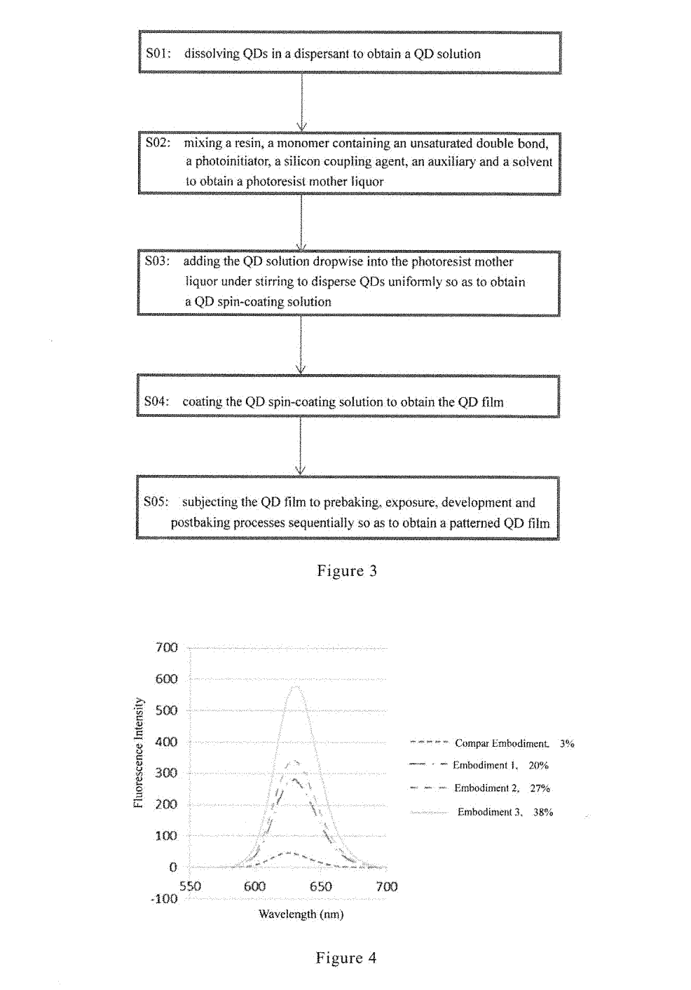

As illustrated in FIG. 3, another aspect of the embodiments of the present disclosure provides a patterning method of a quantum dot film, the patterning method comprising the following steps:

Step 1: dissolving quantum dots in a dispersant to obtain a quantum dot solution.

In this step, greater than 0 and less than or equal to about 60 parts by weight of quantum dots are dissolved in from about 5 to about 90 parts by weight of a dispersant to obtain a quantum dot solution.

Step 2: mixing a resin, a monomer containing an unsaturated double bond, a photoinitiator, a silicon coupling agent, an auxiliary and a solvent to obtain a photoresist mother liquor.

In this step, from about 5 to about 45 parts by weight of a resin, from about 0.5 to about 18 parts by weight of a monomer containing an unsaturated double bond, from about 0.1 to about 3 parts by weight of a photoinitiator, from about 0.1 to about 7 parts by weight of a silicon coupling agent, from about 0.1 to about 1 part of weight of an auxiliary and from about 40 to about 85 parts by weight of a solvent are mixed to obtain a photoresist mother liquor.

Step 3: adding the quantum dot solution dropwise to the photoresist mother liquor under stirring to disperse the quantum dots uniformly so as to obtain a quantum dot spin-coating solution.

In this step, the quantum dot solution obtained above is added dropwise to the photoresist mother liquor. Dropwise adding or slow adding enables the quantum dot solution to be dispersed more uniformly in the photoresist mother liquor so as to obtain a clear and translucent quantum dot spin-coating solution which is uniformly dispersed.

Step 4: coating the quantum dot spin-coating solution on a substrate to form a quantum dot film.

In this step, the above-mentioned quantum dot spin-coating solution can be coated by spin coating to obtain a quantum dot film.

Step 5: subjecting the quantum dot film to prebaking, exposure, development and postbaking processes sequentially to obtain a patterned quantum dot film.

An embodiment of the present disclosure provides a patterning method of a quantum dot film. In this method, the prepared quantum dot film is subjected to prebaking, exposure, development and postbaking processes sequentially so as to obtain a patterned quantum dot film. During preparation of the quantum dot film, quantum dots are first dissolved in a dispersant, and then dispersed in a photoresist such that the quantum dots are dispersed uniformly in the photoresist and aggregation of the quantum dots in the photoresist is avoided. Because quantum dots are effectively dispersed in the photoresist, the parts by weight of the quantum dots dissolved in the photoresist are accordingly increased such that a quantum dot film containing a high concentration of quantum dots can be prepared. This method is simple and suitable for scale operation, and can be extensively applied.

For example, in Step 4, the quantum dot spin-coating solution is coated onto a substrate at from about 200 to about 400 revolutions per minute to form a quantum dot film. It would be appreciated that a person skilled in the art may select a suitable coating rotation rate within the above-mentioned range for coating according to requirements of the process, e.g., 250 revolutions per minute, 300 revolutions per minute, 350 revolutions per minute, 360 revolutions per minute, etc., which are not specifically exemplified herein. In Step 5, the quantum dot film formed is sequentially prebaked at about 50° C.-130° C. for about 3-5 minutes, exposed under about 100-300 MJ, developed in about 0.42% KOH for about 40-90 seconds, and finally postbaked at about 60-150° C. for about 10-60 minutes. Specifically, the prebaking temperature can be 60° C., 70° C., 80° C., 90° C., 100° C., 110° C. or 120° C., wherein 60° C. and 70° C. are preferred; the postbaking temperature can be 70° C., 80° C., 90° C., 100° C., 110° C., 120° C., 130° C. or 140° C., wherein 80° C. is preferred. It would be appreciated that a person skilled in the art may select suitable conditions such as temperature and time within the above-mentioned ranges, which will not be specifically exemplified herein. In this embodiment, by adjusting process parameters on the basis of the original process, the quantum dot film may better maintain the quantum dot concentration and brightness in a patterning process, thereby obtaining a patterned quantum dot film comprising a high concentration of quantum dots.

In order to illustrate the quantum dot film, its preparation method, its patterning method and its display device provided by the present disclosure, the quantum dot film and the patterned quantum dot film prepared are specifically illustrated below by taking red quantum dots as an example.

### Embodiment 1

0.011 g of quantum dots were dissolved in 200 μL of a dispersant, and subjected to ultrasonic treatment to fully dissolve the quantum dots, thereby obtaining a quantum dot solution. The quantum dot solution was then added dropwise to 200 μL of a photoresist mother liquor (containing a resin, a monomer containing an unsaturated double bond, a photoinitiator, a silicon coupling agent, an auxiliary and a solvent) and subjected to ultrasonic treatment for 10 minutes, thereby obtaining a quantum dot spin-coating solution. The quantum dot spin-coating solution was coated at 6 resolutions per second to obtain an even and uniform quantum dot film with a thickness of 1.8 μm.

After calculation of the quantum dots and the photoresist mother liquor in Embodiment 1, the photoresist mother liquor had a solid content of 22.9%, and the parts by weight of the red quantum dots in the dry film were 20% after removal of the solvent.

### Embodiment 2

0.017 g of quantum dots were dissolved in 200 μL of a dispersant, and subjected to ultrasonic treatment to fully dissolve the quantum dots, thereby obtaining a quantum dot solution. The quantum dot solution was then added dropwise in 200 μL of a photoresist mother liquor (containing a resin, a monomer containing an unsaturated double bond., a photoinitiator, a silicon coupling agent, an auxiliary and a solvent) and subjected to ultrasonic treatment for 10 minutes, thereby obtaining a quantum dot spin-coating solution. The quantum dot spin-coating solution was coated at 6 resolutions per second to obtain an even and uniform quantum dot film with a thickness of 1.6 μm.

After calculation of the quantum dots and the photoresist mother liquor in Embodiment 2, the photoresist mother liquor had a solid content of 22.9%, and the parts by weight of the red quantum dots in the dry film were 27% after removal of the solvent.

### Embodiment 3

0.028 g of quantum dots were dissolved in 200 μL of a dispersant, and subjected to ultrasonic treatment to fully dissolve the quantum dots, thereby obtaining a quantum dot solution. The quantum dot solution was then added dropwise in 200 μL of a photoresist mother liquor (containing a resin, a monomer containing an unsaturated double bond, a photoinitiator, a silicon, coupling agent, an auxiliary and a solvent) and subjected to ultrasonic treatment for 10 minutes, thereby obtaining a quantum dot spin-coating solution. The quantum dot spin-coating solution was coated at 6 resolutions per second to obtain an even and uniform quantum dot film with a thickness of 1.5 μm.

After calculation of the quantum dots and the photoresist mother liquor in Embodiment 3, the photoresist mother liquor had a solid content of 22.9%, and the parts by weight of the red quantum dots in the dry film were 38% after removal of the solvent.

### Comparative Embodiment

0.006 g of red quantum dots were directly added to 1000 μL of a photoresist mother liquor to obtain a quantum dot spin-coating solution containing no dispersant. The quantum dot spin-coating solution containing no dispersant was coated at 6 resolutions per second to obtain a quantum dot film with a thickness of 1.8 μm.

After calculation of the red quantum dots in the comparative embodiment, the parts by weight of the red quantum dots in the dry film were 3 wt % after removal of the solvent.

Fluorescent Test

The fluorescence spectrums of the quantum dot films obtained in Embodiments 1-3 and the Comparative Embodiment were observed, wherein the conditions for the fluorescent test were as follows: exciting wavelength, 370 nm; emission slit, 2.5 nm; reception slit, 10 nm; and scanning speed, 600 nm/min. The result of the fluorescent test is as illustrated in FIG. 4.

As illustrated in FIG. 4, for the Comparative Embodiment wherein no dispersant was added and the parts by weight of the red quantum dots incorporated were 3%, the fluorescence intensity observed at 625 nm was only 50 (it should be noted that tests have demonstrated that the maximum parts by weight of the quantum dots added were only 3% when no dispersant was added in the Comparative Embodiment, and the addition of more quantum dots would lead to severe aggregation). With the addition of a dispersant and the increase of the parts by weight of the red quantum dots, the fluorescence intensity observed at 625 nm was also increased, and the maximum fluorescence intensity observed was 580 when the parts by weight of the red quantum dots were 38%, which is 10 times higher than the fluorescence intensity tested in the Comparative Embodiment. It can be seen that the fluorescence intensity of the quantum dot film prepared in Embodiments 1-3 of the present application is significantly increased in comparison with the fluorescence intensity of the quantum dot film prepared in the Comparative Embodiment.

IVL (Current-Voltage-Luminance) Test

IVL test conditions: a blue LED is used as backlight excitation to observe the brightness of the quantum dot films obtained by Embodiments 1-3 and the Comparative Embodiment, wherein the backlight intensity is 334.6 cd/cm²; and the backlight color coordinates are: x=0.1578, y=0.018. The test result is shown in Table 1.

TABLE 1
Brightness of the quantum dot films obtained by
Embodiments 1-3 and the Comparative Embodiment

| Dry film concentration (%) | Brightness (cd/cm²) |
|---|---|
| Comparative Embodiment, 3% | 0 |
| Embodiment 1, 20% | 55.44 |
| Embodiment 2, 27% | 57.08 |
| Embodiment 3, 38% | 128.40 |

As can be seen from the data in Table 1, the quantum dot film without addition of a dispersant in the Comparative Embodiment had a too low brightness to be detected by an instrument. However, in Embodiments 1-3, with the addition of a dispersant and the increase of the parts by weight of the quantum dots, the brightness was significantly increased such that the brightness and color gamut of light in the display device prepared by using the quantum dot film can be effectively improved during transmission, thereby improving the overall performance of the display device and the quality of the display image.

Patterning Test

Then, a patterning test was carried out by using the quantum dot films prepared by a method similar to Embodiment 1 (coating rotation rate is 360, 200 or 300 resolutions per minute). As illustrated in Table 2, four tests were carried out for patterning of the quantum dot film, wherein the condition parameters of prebaking, exposure and development were fixed. The technical parameters for preparing a quantum dot film with excellent performance were analyzed by adjusting the coating rotation rate and the postbaking time and by using the brightness of the quantum dot film as a criterion.

TABLE 2
Data of subjecting the quantum dot film prepared by Embodiment 1
to a patterning test

| | coating rotation | | | | | | brightness | brightness |
|---|---|---|---|---|---|---|---|---|
| | rate | | | | | film | before the | after the |
| | (resolutions per | | | | | thickness | patterning process | patterning process |
| No. | minute) | prebaking | exposure | development | postbaking | (μm) | (cd/cm²) | (cd/cm²) |
| 1 | 360 | 60° C. | 200 MJ | 60 seconds | 80° C. | 1.61 | 81 | 48 |
| | | 3 minutes | | | 10 minutes | | | |
| 2 | 200 | | | | 80° C. | 2.54 | 98 | 53 |
| | | | | | 20 minutes | | | |
| 3 | 200 | | | | 80° C. | 2.4 | 96 | 62 |
| | | | | | 10 minutes | | | |
| 4 | 300 | | | | 80° C. | 1.76 | 87 | 56 |
| | | | | | 10 minutes | | | |

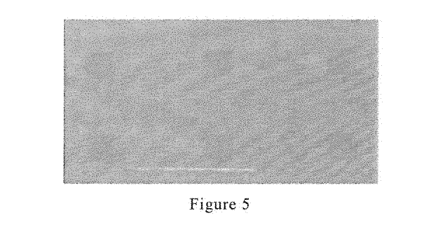

It can be seen from the above table that the tests No. 1, 3 and 4 are different in terms of the coating rotation rate. By comparing the thickness and brightness of the patterned quantum dot films obtained by these three tests, it can be seen that the thickness of the patterned quantum dot film No. 3 is slightly greater than that of No. 4 which is slightly greater than that of No. 1, and that the brightness of No. 3 is greater than that of No. 4 which is greater than that of No. 1. Therefore, it can be determined that the coating rotation rate has a certain impact on the thickness and brightness of the patterned quantum dot film and a smaller coating rotation rate should help to obtain a thicker patterned quantum dot film and maintain the brightness thereof. Afterwards, the brightness of the patterned quantum dot film Nos. 2 and 3 obtained were compared. It can be seen from the brightness data that the postbaking duration has a certain impact on the brightness: a high postbaking temperature would quench the quantum dots and a relatively shorter postbaking time is better. Thus, as can be seen from the above four tests, the performance of the patterned quantum dot film obtained under the condition parameters of No. 3 was the best. Therefore, the patterned quantum dot film was prepared according to the condition parameters of No. 3, as illustrated in FIG. 5.

It can be seen from the brightness data of No. 3 in the above table, the brightness of the quantum dot film before the patterning process was 96 cd/m², and the brightness after the patterning process was 62 cd/m². The brightness maintained greater than 65% of the initial value, which is far beyond the reference criteria of maintaining greater than 50% of the initial value after the patterning process in the prior art. As such, it can be seen that, the patterning method of the quantum dot film provided by the embodiments of the present application can prepare a patterned quantum dot film having a high concentration of quantum dots, thereby effectively improving the overall performance of the display device and the quality of the display image. It shall be noted that a patterned quantum dot film containing 20% parts by weight of quantum dots can be prepared in the present process, which is much better than the prior art which can only prepare a patterned quantum dot film containing 3% parts by weight of quantum dots. Moreover, the patterned quantum dot film containing 20% parts by weight of quantum dots is sufficient to meet the requirements of being a light-emitting layer of a display device.

Apparently, the above embodiments are merely for clearly illustrating other than limitation to the invention, and other variations or changes may be made by a person skilled in the art based on the above illustration. All embodiments cannot or need not be listed exhaustively herein. However, these obvious variations or changes derived therefrom still fall into the scope of protection of the present invention.

The present application claims the benefits of the Chinese Application No. 201610004896.X filed on Jan. 4, 2016, the entire disclosure of which is incorporated herein by reference.

What is claimed is:

1. A quantum dot film, which is prepared from the following raw materials:
quantum dots, greater than 0 and less than or equal to about 60 parts by weight;
a dispersant, from about 5 to about 90 parts by weight;
a resin, from about 5 to about 45 parts by weight;
a monomer containing an unsaturated double bond, from about 0.5 to about 18 parts by weight;
a photoinitiator, from about 0.1 to about 3 parts by weight;
a silicon coupling agent, from about 0.1 to about 7 parts by weight;
an auxiliary, from about 0.1 to about 1 part of weight; and
a solvent, from about 40 to about 85 parts by weight.

2. The quantum dot film according to claim 1, wherein the quantum dot film comprises greater than 0 wt % and less than or equal to about 60 wt % of the quantum dots after being dried.

3. The quantum dot film according to claim 2, wherein the quantum dot film has a dry film thickness of from about 1.5 μm to about 3 μm.

4. The quantum dot, film according to claim 1, wherein the quantum dot comprises at least one or a combination of two or more of CdS, CdSe, CdTe, ZnS, ZnSe, ZnTe, HgS, HgTe, GaN, GaAs, InP, and InAs.

5. The quantum dot film according to claim 1, wherein the quantum dot is CdSe/ZnS type red quantum dot or CdSe/ZnS type green quantum dot.

6. The quantum dot film according to claim 5, wherein the CdSe/ZnS type red quantum dot is from about 3 to about 40 parts by weight, and the CdSe/ZnS type green quantum dot is from about 3 to about 40 parts by weight.

7. The quantum dot film according to claim 1, wherein the dispersant is selected from at least one or a combination of two or more of chloroform, tetrahydrofuran, methylene chloride, toluene, n-hexane, methanol, ethanol, propanol, butanol, acetone, dioxane, dimethyl formamide and dimethyl sulfoxide.

8. A display device comprising the quantum dot film according to claim 1.

9. A preparation method of a quantum dot film, wherein the preparation method comprises the following steps:
dissolving quantum dots in a dispersant to obtain a quantum dot solution;
mixing a resin, a monomer containing an unsaturated double bond, a photoinitiator, a silicon coupling agent, an auxiliary and a solvent to obtain a photoresist mother liquor;
adding the quantum dot solution dropwise into the photoresist mother liquor under stirring to disperse the quantum dots uniformly so as to obtain a quantum dot spin-coating solution; and
coating the quantum dot spin-coating solution to obtain the quantum dot film.

10. The preparation method according to claim 9, wherein the quantum dots are dispersed uniformly by means of ultrasound or stirring.

11. A patterning method of a quantum dot film, wherein the method comprises the following steps:
dissolving quantum dots in a dispersant to obtain a quantum dot solution;
mixing a resin, a monomer containing an unsaturated double bond, a photoinitiator, a silicon coupling agent, an auxiliary and a solvent to obtain a photoresist mother liquor;
adding the quantum dot solution dropwise into the photoresist mother liquor under stirring to disperse the quantum dots uniformly so as to obtain a quantum dot spin-coating solution;
coating the quantum dot spin-coating solution onto a substrate to form a quantum dot film; and
subjecting the quantum dot film to prebaking, exposure, development and postbaking processes sequentially, so as to obtain a patterned quantum dot film.

12. The patterning method according to claim 11; wherein the quantum dot spin-coating solution is coated onto the substrate at from about 200 to about 400 revolutions per minute to form the quantum dot film; the formed quantum dot film is sequentially prebaked at a temperature of from about 50° C. to about 130° C. for from about 3 to about 5 minutes, exposed under from about 100 to about 300 MJ, developed in about 0.42% KOH for from about 40 to about 90 seconds, and postbaked at a temperature of from about 60 to about 150° C. for from about 10 to about 60 minutes.
